(19) United States
(12) Patent Application Publication
(10) Pub. No.: US 2010/0001305 A1
(43) Pub. Date: Jan. 7, 2010

(54) SEMICONDUCTOR DEVICES AND FABRICATION METHODS THEREOF

(75) Inventors: Chun-Chi LIN, Hsinchu (TW); Tzu-Han LIN, Hsinchu (TW); Chien-Chen HSIEH, Hsinchu (TW)

Correspondence Address: Muncy, Geissler, Olds & Lowe, PLLC, P.O. BOX 1364, FAIRFAX, VA, 22038-1364, US

(73) Assignee: VisEra Technologies Company Limited

(21) Appl. No.: 12/168,559

(22) Filed: Jul. 7, 2008

(51) Int. Cl. H01L 33/00

(52) U.S. Cl. 257/99; 438/66; 257/E33.059

(57) ABSTRACT

A semiconductor device and a fabrication method thereof are provides. The semiconductor device comprises a semiconductor substrate having a cavity and a light-emitting diode chip disposed in the cavity. The cavity is filled with an encapsulating resin to cover the light-emitting diode chip. Two isolated metal lines are disposed on the encapsulating resin and electrically connected to the light-emitting diode chip. At least two isolated inner wiring layers are disposed in the cavity and electrically connected to the isolated metal lines. At least two isolated outer wiring layers are disposed on a bottom surface of the semiconductor substrate and electrically connected to the isolated inner wiring layers.

### BACKGROUND OF THE INVENTION

1. Field of the Invention

The invention relates to a light-emitting diode (LED) device and more particularly to LED devices without wire bonding.

2. Description of the Related Art

Light-emitting diodes (LEDs) are solid-state light sources with multiple-advantages. They are capable of reliably providing light with high brightness and thus are applied in displays, traffic lights and indicators. LEDs are fabricated by depositing an n-doped region, an active region and a p-doped region on a substrate. Some LEDs have an n-contact formed on one side of a device and a p-contact formed on the opposite side of the device. Other LEDs have both contacts formed on the same side of a device.

In general, there are two types of an LED package structures. One is a wire bonded LED device as shown in FIG. 1, wherein an LED chip 12 is attached to a substrate 10. The n-contact and the p-contact are both on the same side of the LED chip 12. Two wires 14 are then connected to the contacts of the LED chip 12 respectively and electrically connected to the leads on the substrate 10 by wire bonding. However, the wire bonded LED devices have several drawbacks. First, the wires are fragile and thus have reliability problems when transmitting signals between the LED chip 12 and the leads on the substrate 10. Second, the wire bonded LED requires space on the substrate outside of the footprint of the LED chip 12 for the wires 14, resulting in larger and more expensive devices. Third, the wire bonding process is time-consuming and thus yield rates are lower.

The other package structure is a flip chip type LED device as shown in FIG. 2, wherein an LED chip 12 is mounted on a substrate 10 with the contacts facing toward the substrate 10. The contacts of the LED chip 12 are connected to the leads of the substrate 10 through solder balls 16. Although the reliability of the devices can be improved by the flip chip type packages, the LED chip used for the flip chip type package is more expensive than that of the wire bonded type package and the fabrication of flip chip type LED devices is difficult.

Therefore, an LED device capable of overcoming the above problems is desired.

### BRIEF SUMMARY OF THE INVENTION

A semiconductor device and a fabrication method thereof are provided. The semiconductor device for a light-emitting diode chip package has no wire bonding. An exemplary embodiment of the semiconductor device comprises a semiconductor substrate having a cavity and a light-emitting diode chip disposed in the cavity. The cavity is filled with an encapsulating resin to cover the light-emitting diode chip. At least two isolated metal lines are disposed on the encapsulating resin and electrically connect to the light-emitting diode chip. At least two isolated inner wiring layers are disposed in the cavity and electrically connect to the isolated metal lines. At least two isolated outer wiring layers are disposed on a bottom surface of the semiconductor substrate and electrically connect to the isolated inner wiring layers.

An exemplary embodiment of the method for fabricating the semiconductor devise comprises providing a semiconductor wafer, having a first surface and a second surface. A plurality of cavities is formed on the first surface of the semiconductor wafer. A patterned inner wiring layer is formed on the first surface of the semiconductor wafer and in the cavities. A patterned outer wiring layer is formed on the second surface of the semiconductor wafer and electrically connected to the patterned inner wiring layer. A plurality of light-emitting diode chips is disposed in the corresponding cavities. Then, the cavities are filled with an encapsulating resin to cover the light-emitting diode chips. A metal layer is formed on the encapsulating resin and the patterned inner wiring layer, wherein the metal layer is electrically connected to the light-emitting diode chips by passing through the encapsulating resin. Then, the metal layer is patterned to form two isolated metal lines on the encapsulating resin. The semiconductor wafer between the adjacent cavities is then divided to form a plurality of semiconductor devices.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 is a schematic cross section of a conventional wire bonded type LED device;

FIG. 2 is a schematic cross section of a conventional flip chip type LED device;

FIGS. 3A to 3H are cross sections of an exemplary embodiment of a method for fabricating LED devices according to the invention; and

FIGS. 4A to 4E are cross sections of another exemplary embodiment of a method for fabricating LED devices according to the invention.

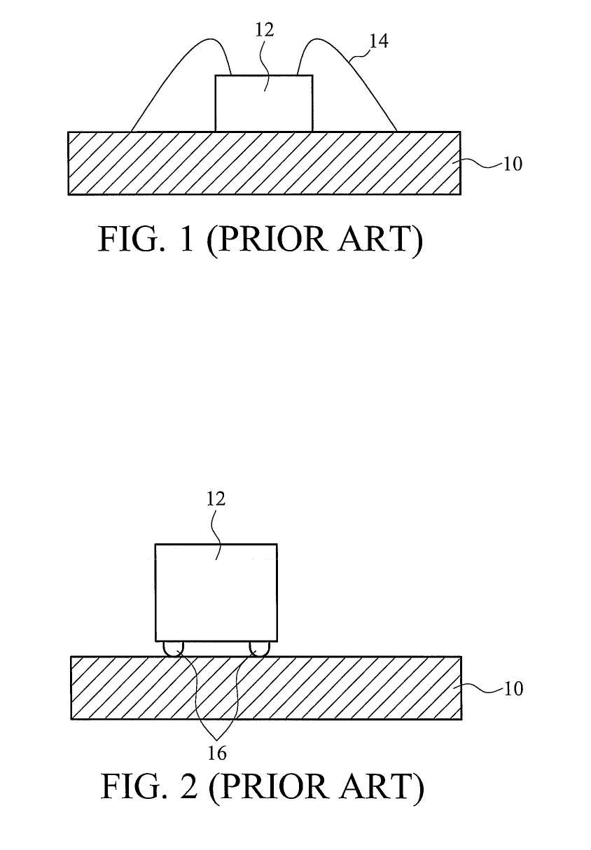

### DETAILED DESCRIPTION OF INVENTION

The following description is of the best-contemplated mode of carrying out the invention. This description is made for the purpose of illustrating the general principles of the invention and should not be taken in a limiting sense. The scope of the invention is best determined by reference to the appended claims.

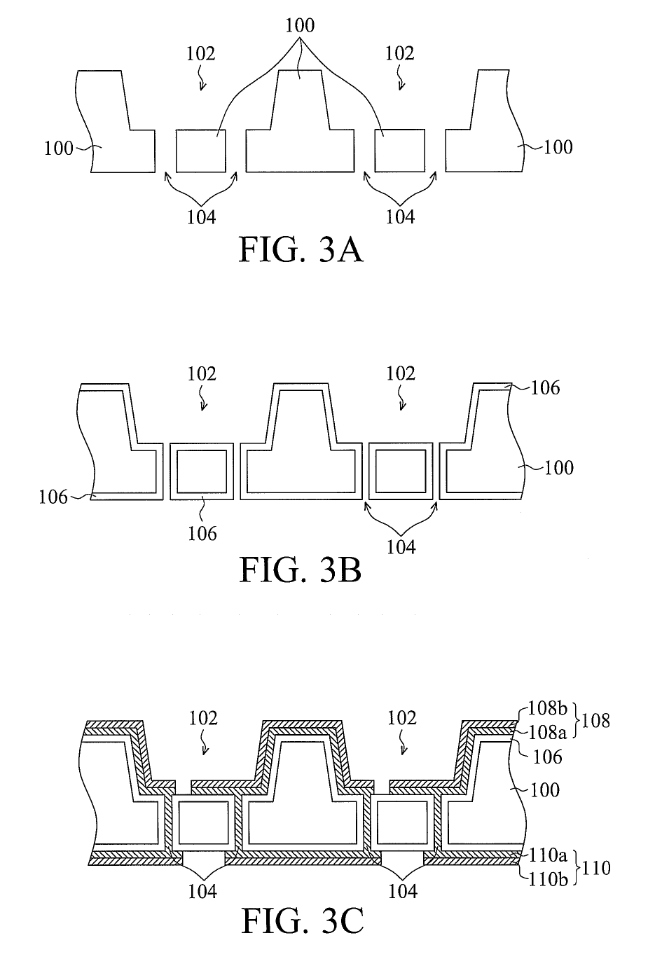

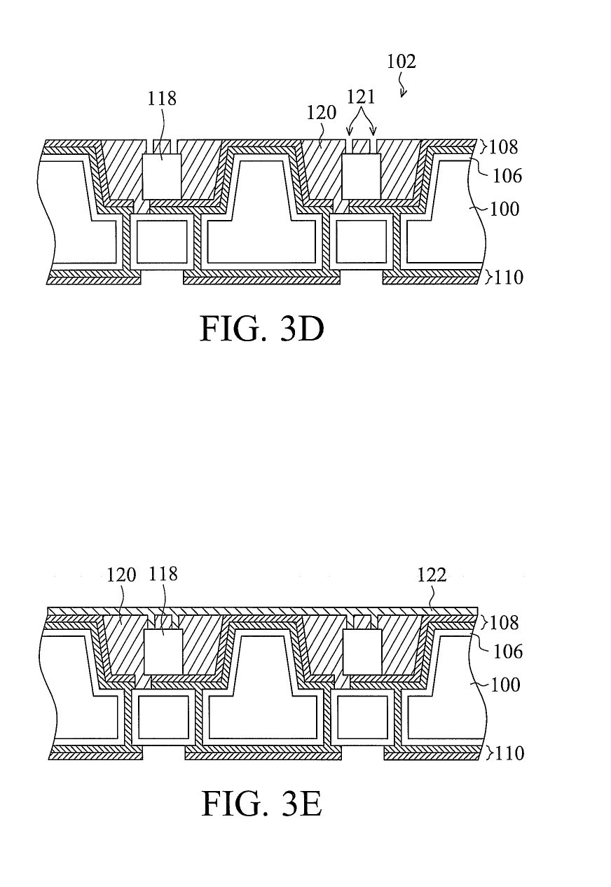

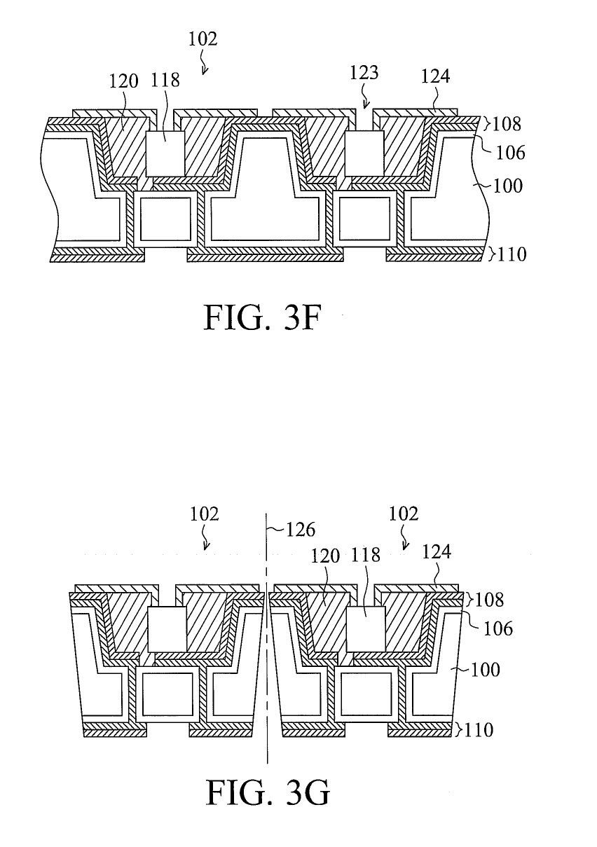

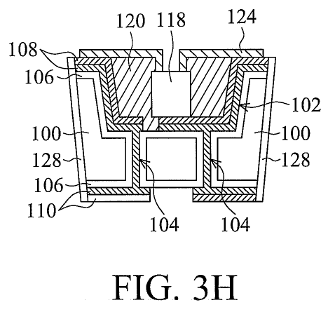

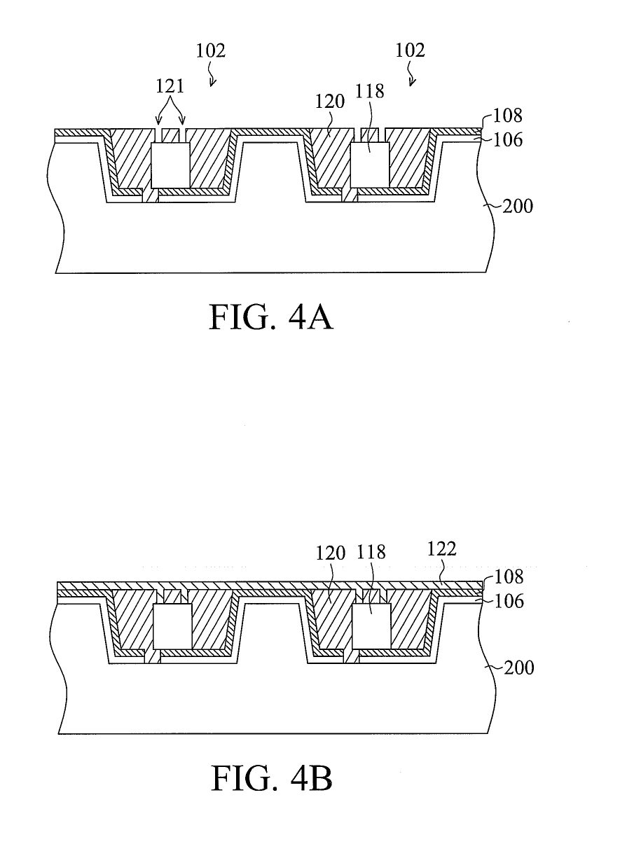

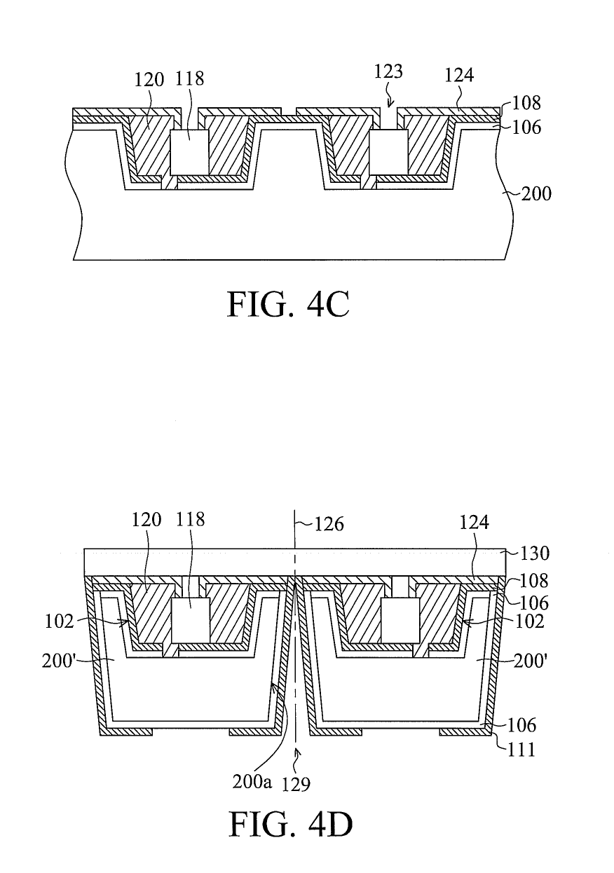

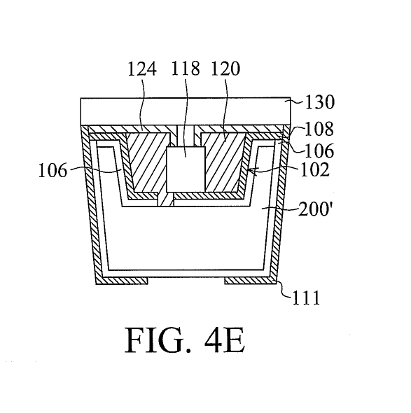

The invention provides LED package structures without wire bonding. FIGS. 3H and 4E show cross sections of exemplary embodiments of an LED devices according to the invention. Referring to FIG. 3H, the LED device comprises a semiconductor substrate 100 such as a silicon substrate or other semiconductor substrates. The semiconductor substrate 100 may contain a variety of elements, including, for example, transistors, resistors, and other semiconductor elements. In order to simplify the diagram, the variety of elements is not depicted. A cavity 102 is formed on an upper surface of the semiconductor substrate 100. At least two through holes 104 are formed under the cavity 102, passing through the semiconductor substrate 100. At least two isolated inner wiring layers 108 are disposed in the cavity 102 and on the upper surface of the semiconductor substrate 100. At least two isolated outer wiring layers 110 are disposed on a bottom surface of the semiconductor substrate 100, serving as input terminals. The isolated inner wiring layers 108 are connected to the isolated outer wiring layers 110 by the through holes 104, respectively. A light-emitting diode (LED) chip 118 is disposed in the cavity 102. Then, the cavity 102 is filled with an encapsulating resin 120 to cover the LED chip 118. Two isolated metal lines 124 are formed on the encapsulating resin 120, passing through the encapsulating resin 120 to connect with a p-contact and an n-contact of the LED chip 118, respectively. The two isolated metal lines 124 are also electrically connected to the isolated inner wiring layers 108, respectively. In the LED device of FIG. 3H, there is no wire bonding used for electrical connection between the LED chip and the inner wiring layers.

Referring to FIG. 4E, another embodiment of an LED device. The LED device comprises a semiconductor substrate 200′ having a cavity 102. At least two isolated inner wiring layers 108 are disposed in the cavity 102 and on the upper surface of the semiconductor substrate 200′. A light-emitting diode (LED) chip 118 is disposed in the cavity 102. Then, the cavity 102 is filled with an encapsulating resin 120 to cover the LED chip 118. Two isolated metal lines 124 are formed on the encapsulating resin 120, passing through the encapsulating resin 120 to connect with the p-contact and the n-contact of the LED chip 118, respectively. The two isolated metal lines 124 are also electrically connected to the isolated inner wiring layers 108, respectively. In this embodiment, there is no through hole under the cavity 102. At least two outer wiring layers 111 are disposed on a bottom surface of the semiconductor substrate 200′ and extend to sidewalls of the semiconductor substrate 200′ for electrically connecting to the inner wiring layers 108. In addition, a glass plate 130 is disposed over the LED chip 118.

Referring to FIGS. 3A to 3H, which are cross sections of an exemplary embodiment of a method for fabricating LED devices according to the invention. As shown in FIG. 3A, a semiconductor substrate 100, such as a silicon wafer or other semiconductor wafers is provided. A plurality of cavities 102 is formed adjacent to each other on an upper surface of the semiconductor wafer 100 by a wet etching or dry etching process. At least two through holes 104 are formed under each cavity 102 by the wet etching process. In order to simplify the diagram, only two adjacent cavities 102 and only two through holes 104 under each cavity 102 are depicted.

As shown in FIG. 3B, an insulating layer 106 such as a silicon oxide layer is conformally formed on the upper surface and the bottom surface of the semiconductor wafer 100, the inner surface of each cavity 102 and the sidewalls of each through hole 104 by a thermal oxidation, chemical vapor deposition (CVD) or other conventional deposition process. Referring to FIG. 3C, a first metal layer (not shown) is conformally formed on the insulating layer 106 overlying the upper surface of the semiconductor wafer 100, the inner surfaces of the cavities 102 and fills the upper portions of the through holes 104 by a sputtering process. The thickness of the first metal layer may be about 2˜3 μm. Next, a second metal layer (not shown) is conformally formed on the insulating layer 106 overlying the bottom surface of the semiconductor wafer 100 and fills the lower portions of the through holes 104 by a sputtering process. The thickness of the second metal layer may be about 2˜3 μm. As a result, the first metal layer is connected with the second metal layer by the through holes 104. Then, the first and the second metal layers are patterned by a photolithography and etching process to form patterned metal layers 108a and 110a, respectively. Then, metal layers 108b and 110b are deposited on the patterned metal layers 108a and 110a respectively by electroplating to form at least two isolated inner wiring layers 108 in each cavity 102 and at least two isolated outer wiring layers 110 on the bottom surface of the semiconductor wafer 100 for each cavity 102. The inner wiring layers 108 extend to the upper surface of the semiconductor wafer 100. The metal layers 108a and 110a may be aluminum (Al), copper (Cu) or alloys thereof. The metal layers 108b and 110b may be nickel (Ni), gold (Au), silver (Ag) or alloys thereof. The thicknesses of the inner wiring layer 108 and the outer wiring layer 110 may be about 5 μm.

Referring to FIG. 3D, a plurality of LED chips 118 are correspondingly provided in the plurality of cavities 102. Then, the cavities 102 are filled with a transparent encapsulating resin 120 to cover the LED chips 118. The encapsulating resin 120 may be a photosensitive resin, such that two openings 121 which can be formed in the encapsulating resin 120 by exposure and development to expose the contacts of the LED chip 118. Referring to FIG. 3E, a metal layer 122 is deposited on the encapsulating resin 120 and the upper surface of the semiconductor wafer 100 by a sputtering process. The openings 121 are also filled with the metal layer 122 at the same time.

Referring to FIG. 3F, the metal layer 122 is then patterned by a photolithography and etching process to form two isolated metal lines 124 on the encapsulating resin 120 for each LED chip 118. In this step, the portions of the encapsulating resin 120 and the metal layer 122 between the isolated metal lines 124 are removed by etching to form an opening 123. The two isolated metal lines 124 are connected to the p-contact and the n-contact (not shown) of the LED chip 118 by passing through the encapsulating resin 120. In addition, the two isolated metal lines 124 are also electrically connected to the isolated inner wiring layers 108, respectively.

Referring to FIG. 3G, the semiconductor wafer 100 are divided along a scribe line 126 between the adjacent cavities 102 to form a plurality of semiconductor devices. Referring to FIG. 3H, an insulating layer 128 may be coated on the sidewalls of the semiconductor substrate 100, covering the sides of the inner wiring layers 108 and the outer wiring layers 110 to protect the wiring layers 108 and 110. In this embodiment, there is no wire bonding between the LED chip 118 and the inner wiring layers 108.

Referring to FIGS. 4A to 4E, which are cross sections of another exemplary embodiment of a method for fabricating LED devices according to the invention. Elements in FIGS. 4A to 4E that are the same as those in FIGS. 3A to 3H are labeled with the same reference numbers and are not described again for brevity. As shown in FIG. 4A, a semiconductor wafer 200 comprising a plurality of cavities 102 adjacent to each other is provided.

An insulating layer 106 such as a silicon oxide layer is conformally formed by a thermal oxidation, chemical vapor deposition (CVD) or other conventional deposition process on the upper surface of the semiconductor wafer 200 and the inner surface of each cavity 102. Next, a first metal layer (not shown) is conformally formed on the insulating layer 106 overlying the upper surface of the semiconductor wafer 200 and the inner surface of each cavity 102. The first metal layer is then patterned by a photolithography and etching process to form at least two isolated inner wiring layers 108 in each cavity 102.

A plurality of LED chips 118 are correspondingly provided in the plurality of cavities 102. Then, the cavities 102 are filled with a transparent encapsulating resin 120 to cover the LED chips 118. The encapsulating resin 120 may be a photosensitive resin, wherein two openings 121 can be formed in the encapsulating resin 120 by an exposure and development process to expose the contacts of the LED chip 118.

Referring to FIG. 4B, a metal layer 122 is formed on the encapsulating resin 120 and the upper surface of the semiconductor wafer 100 by a sputtering process. The openings 121 are also filled with the metal layer 122 at the same time. Referring to FIG. 4C, the metal layer 122 is patterned by a photolithography and etching process to form two isolated metal lines 124 on the encapsulating resin 120 for each LED chip 118. In this step, the portions of the encapsulating resin 120 and the metal layer 122 between the two isolated metal lines 124 can be removed by etching to form an opening 123. The two isolated metal lines 124 are connected to the p-contact and the n-contact (not shown) of the LED chip 118 by passing through the encapsulating resin 120. In addition, the two isolated metal lines 124 are also electrically connected to the isolated inner wiring layers 108, respectively.

Referring to FIG. 4D, the upper surface of the semiconductor wafer 200 is attached to a glass plate 130. The backside of the semiconductor wafer 200 is then thinned by a grinding process. Next, the backside of the thin semiconductor wafer is etched to form a plurality of notches 129 between the adjacent cavities 102 to form individual semiconductor substrates 200′. An insulating layer 106 such as a silicon oxide layer is conformally formed by a thermal oxidation, chemical vapor deposition (CVD) or other conventional deposition process on the bottom surface and the sidewalls of each semiconductor substrate 200′. Then, a second metal layer (not shown) is conformally formed on the insulating layer 106 overlying the bottom surface and the sidewalls of each semiconductor substrate 200′. The second metal layer is then patterned by a photolithography and etching process to form at least two isolated outer wiring layers 111 on the bottom surface of each semiconductor substrate 200′, extending along the sidewalls 200a of the semiconductor substrate 200′ to connect with the isolated inner wiring layers 108, respectively. The isolated inner wiring layers 108 and the isolated outer wiring layers 111 may consist of two metal layers formed by a sputtering and electroplating process. The two metal layers may be aluminum (Al), copper (Cu), nickel (Ni), gold (Au), or silver (Ag) or alloys thereof. The thicknesses of the inner wiring layer 108 and the outer wiring layer 111 may be about 5 μm.

The semiconductor wafer is then divided along a scribe line 126 in the notch 129 to form a plurality of semiconductor devices as shown in FIG. 4E. In this embodiment, there is no wire bonding between the LED chip 118 and the inner wiring layers 108.

Although there is no other element depicted over the LED chip in the semiconductor devices of FIGS. 3H and 4E. A lens module and a fluorescent layer can be disposed over the LED chip package structure.

According to the aforementioned embodiments, the LED chip can be electrically connected to the inner wiring layers through the metal lines formed by a photolithography process. There is no wire bonding used in the semiconductor devices of the exemplary embodiments of the invention. Therefore, the reliability of connection between the LED chip and the inner wiring layers can be enhanced. Meanwhile, because the LED package structures according to the invention have no wire bonding, the space for the wires when wire bonding can be saved. Accordingly, the area of the carrier substrate for the LED package can be reduced and the yield rates of the products in a unit of the substrate area can be increased. Moreover, the LED chips used for the semiconductor devices of the exemplary embodiments of the invention can be the same as the LED chips of wire bonded LED packages. Therefore, the cost of LED chips ill the semiconductor devices of the invention is much less than that of flip chip LED packages.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a semiconductor substrate, having a cavity on an upper surface of the semiconductor substrate;
a light-emitting diode chip disposed in the cavity;
an encapsulating resin disposed in the cavity, covering the light-emitting diode chip;
two isolated metal lines disposed on the encapsulating resin and electrically connecting to the light-emitting diode chip;
at least two isolated inner wiring layers disposed in the cavity and electrically connected to the isolated metal lines; and
at least two isolated outer wiring layers disposed on a bottom surface of the semiconductor substrate and electrically connected to the isolated inner wiring layers.

2. The semiconductor device as claimed in claim 1, wherein the semiconductor substrate comprises at least two through holes under the cavity and the isolated inner wiring layers are electrically connected to the isolated outer wiring layers by the through holes, respectively.

3. The semiconductor device as claimed in claim 2, further comprising a first insulating layer disposed between the inner wiring layers and the semiconductor substrate, between the outer wiring layers and the semiconductor substrate, and on the sidewalls of the through holes.

4. The semiconductor device as claimed in claim 2, further comprising a second insulating layer disposed on the sidewalls of the semiconductor substrate, covering the sides of the outer wiring layers and the inner wiring layers.

5. The semiconductor device as claimed in claim 1, wherein the isolated outer wiring layers extend to sidewalls of the semiconductor substrate, directly connecting to the isolated inner wiring layers, respectively.

6. The semiconductor device as claimed in claim 5, further comprising an insulating layer disposed between the inner wiring layers and the semiconductor substrate and between the outer wiring layers and the semiconductor substrate.

7. The semiconductor device as claimed in claim 1, wherein the outer wiring layers and the inner wiring layers comprise at least two metal layers.

8. The semiconductor device as claimed in claim 1, wherein the encapsulating resin comprises a photosensitive resin.

9. The semiconductor device as claimed in claim 1, wherein the encapsulating resin has two openings to expose the light-emitting diode chip and the two isolated metal lines are connected with the light-emitting diode chip through the two openings.

10. A method for fabricating semiconductor devices, comprising:
providing a semiconductor wafer, having a first surface and a second surface opposite to the first surface;
forming a plurality of cavities on the first surface of the semiconductor wafer;
forming a patterned inner wiring layer on the first surface of the semiconductor wafer and in the cavities;
forming a patterned outer wiring layer on the second surface of the semiconductor wafer and electrically connected to the patterned inner wiring layer;
providing a plurality of light-emitting diode chips in the corresponding cavities;
filling the cavities with an encapsulating resin to cover the light-emitting diode chips;
forming a metal layer on the encapsulating resin and the patterned inner wiring layer, wherein the metal layer is electrically connected to the light-emitting diode chips;
patterning the metal layer to form two isolated metal lines on the encapsulating resin for each light-emitting diode chip; and
dividing the semiconductor wafer between the adjacent cavities to form a plurality of semiconductor devices.

11. The method as claimed in claim 10, further comprising forming at least two through holes under each cavity.

12. The method as claimed in claim 11, wherein the patterned inner wiring layer is electrically connected to the patterned outer wiring layer by the through holes.

13. The method as claimed in claim 11, further comprising forming a first insulating layer between the patterned inner wiring layer and the semiconductor wafer, between the patterned outer wiring layer and the semiconductor wafer, and on the sidewalls of the through holes.

14. The method as claimed in claim 11, after the step of dividing the semiconductor wafer, further comprising forming a second insulating layer on the sidewalls of the semiconductor device, covering the sides of the patterned outer wiring layer and the patterned inner wiring layer.

15. The method as claimed in claim 10, wherein the patterned outer wiring layer and the patterned inner wiring layer comprise at least two metal layers.

16. The method as claimed in claim 10, wherein the steps of forming the patterned outer wiring layer and the patterned inner wiring layer comprising sputtering, electroplating, photolithography and etching.

17. The method as claimed in claim 10, before the step of dividing the semiconductor wafer, further comprising:
attaching a glass substrate on the first surface of the semiconductor wafer;
thinning the second surface of the semiconductor wafer; and
etching the second surface of the semiconductor wafer to form a plurality of notches between the adjacent cavities,
wherein the patterned outer wiring layer extends to sidewalls of each semiconductor device, directly connecting to the patterned inner wiring layer.

18. The method as claimed in claim 17, further comprising forming an insulating layer between the patterned inner wiring layer and the semiconductor wafer and between the patterned outer wiring layer and the semiconductor wafer.

19. The method as claimed in claim 10, wherein the encapsulating resin comprises a photosensitive resin.

20. The method as claimed in claim 10, further comprising forming two openings in the encapsulating resin for each light-emitting diode chip, wherein the metal layer is directly connected to the light-emitting diode chips through the openings.
